(19) United States
(12) Patent Application Publication
(10) Pub. No.: US 2022/0352064 A1
(43) Pub. Date: Nov. 3, 2022

(54) GRAPHIC ELEMENT STRUCTURE AND GRAPHIC ARRAY STRUCTURE

(71) Applicant: CHANGXIN MEMORY TECHNOLOGIES, INC., Hefei City (CN)

(72) Inventors: TZUNG-HAN LEE, Hefei City (CN); Hsin-Pin HUANG, Hefei City (CN)

(21) Appl. No.: 17/650,127

(22) Filed: Feb. 7, 2022

Related U.S. Application Data
(63) Continuation of application No. PCT/CN2021/111508, filed on Aug. 9, 2021.

(30) Foreign Application Priority Data
Apr. 28, 2021 (CN) 202110469578.1

(51) Int. Cl. H01L 23/528

(52) U.S. Cl. CPC H01L 23/528

(57) ABSTRACT

The present application discloses a graphic element structure and a graphic array structure. The graphic element structure includes a first graphic, a second graphic, and a third graphic, where the first graphic includes a first part and a second part that are perpendicular to each other, and a tail end of the first part of the first graphic is connected to a head end of the second part of the first graphic; orthographic projection of a first interconnection structure on the first graphic is located in the second part of the first graphic; the second graphic includes a first part and a second part that are perpendicular to each other; orthographic projection of a second interconnection structure on the second graphic is located in the second part of the second graphic; and the third graphic is located between the first graphic and the second graphic.

### CROSS-REFERENCE TO RELATED APPLICATIONS

This is a continuation of International Patent Application No. PCT/CN2021/111508, filed on Aug. 9, 2021, which claims the priority to Chinese Patent Application No. 202110469578.1, titled “GRAPHIC ELEMENT STRUCTURE AND GRAPHIC ARRAY STRUCTURE” and filed with the China National Intellectual Property Administration on Apr. 28, 202. The entire contents of International Patent Application No. PCT/CN2021/111508 and Chinese Patent Application No. 202110469578.1 are incorporated herein by reference.

### TECHNICAL FIELD

The present application relates to the technical field of semiconductors, and in particular, to a graphic element structure and a graphic array structure.

### BACKGROUND

With the rapid development of semiconductor storage technologies, the market has put forward a higher requirement for a storage capability of a semiconductor storage product. For a dynamic random access memory (DRAM), in a back end of line (BEOL) process, multiple adjacent metal layers along a vertical direction are electrically connected via interconnection structures to complete wafer preparation.

However, in a conventional graphic structure with a BEOL layout, a spacing between graphic structures provided with interconnection structures is excessively wide. After the BEOL layout is completed, a passivation layer is deposited to complete wafer preparation. During a reliability test, for example, an unbiased high accelerated stress test (UHAST), in a high temperature and high humidity environment, voids appear in the passivation layer due to an excessively wide spacing area, and the voids will cause an interconnection structure to fall off. Consequently, a prepared wafer is seriously aged, and fails in the reliability test.

### SUMMARY

A first aspect of the present application proposes a graphic element structure, including:

a first graphic, where the first graphic includes a first part and a second part that are perpendicular to each other, a tail end of the first part of the first graphic is connected to a head end of the second part of the first graphic, and the second part of the first graphic extends along a first direction; and orthographic projection of a first interconnection structure on the first graphic is located in the second part of the first graphic;

a second graphic, where the second graphic includes a first part and a second part that are perpendicular to each other, a tail end of the first part of the second graphic is connected to a head end of the second part of the second graphic, the first part of the second graphic is arranged in parallel to the first part of the first graphic, the second part of the second graphic extends along a second direction, and the second direction is opposite to the first direction; and orthographic projection of a second interconnection structure on the second graphic is located in the second part of the second graphic; and

a third graphic, located between the first graphic and the second graphic.

A second aspect of the present application proposes a graphic array structure, including multiple graphic element structures describe above. The multiple graphic element structures are arranged in an array.

### BRIEF DESCRIPTION OF THE DRAWINGS

To describe the technical solutions in the embodiments of the present application more clearly, the following briefly describes the accompanying drawings required for describing the embodiments. Apparently, the accompanying drawings in the following description show merely some embodiments of the present application, and persons of ordinary skill in the art may still derive other drawings from these accompanying drawings without creative efforts.

FIG. 1 is a schematic structural diagram of a graphic element structure according to an embodiment of the present application;

FIG. 2 is a schematic structural diagram of a graphic element structure according to another embodiment of the present application;

FIG. 3 is a schematic structural diagram of a graphic element structure according to still another embodiment of the present application; and

FIG. 4 is a schematic structural diagram of a graphic array structure according to an embodiment of the present application.

### DETAILED DESCRIPTION

To facilitate the understanding of the present application, the present application is described more completely below with reference to the related accompanying drawings. The accompanying drawings show the preferred embodiments of the present application. However, the present application is embodied in various forms without being limited to the embodiments described in this specification. On the contrary, these embodiments are provided for a more thorough and comprehensive understanding of content disclosed in the present application.

Unless otherwise defined, all technical and scientific terms used in this specification have the same meaning as commonly understood by persons skilled in the technical field of the present application. The terms used in this specification of the present application are merely for the purpose of describing specific embodiments, rather than to limit the present application. The term “and/or” used in this specification includes any and all combinations of one or more of associated listed items.

It should be understood that when an element or layer is “on”, “adjacent to”, “connected to”, or “coupled to” another element or layer, the element or layer may be directly on the another element or layer, may be adjacent to, connected to, or coupled to the another element or layer, or there may be an intermediate element or layer. In contrast, when an element is “directly on”, “directly adjacent to”, “directly connected to”, or “directly coupled to” another element or layer, there is no intermediate element or layer. It should be understood that although terms “first”, “second”, “third”, and the like may be used to describe various elements, components, areas, layers, and/or parts, these elements, components, areas, layers, and/or parts should not be limited by these terms. These terms are only used to distinguish one element, component, area, layer, or part from another element, component, area, layer, or part. Therefore, without departing from teachings of the present application, a first element, component, area, layer, or part discussed below may be represented as a second element, component, area, layer, or part.

Herein, for the convenience of description, spatial relation terms such as “under”, “below”, “underlying”, “beneath”, “on”, “above” may be used to describe a relationship between one element or feature shown in a figure and another element or feature. It should be understood that in addition to an orientation shown in the figure, the spatial relation terms are intended to include different orientations of a device in use and operation. For example, if the device in the drawing is turned over, an orientation of an element or feature described as “below” or “beneath” or “under” another element or feature changes to “on” the another element or feature. Therefore, exemplary terms “below” and “under” may include two orientations: “above” and “below”. The device may be in another orientation (rotated by 90 degrees or in another orientation) and a spatial description term used herein is interpreted correspondingly.

The terms used herein are only used for describing specific embodiments and do not constitute any limitation in the present application. When used herein, singular forms “a”, “an”, and “the/this” are also intended to include plural forms, unless otherwise clearly indicated in the context. It should also be understood that, when the terms “composed of” and/or “include” are/is used in this specification, it is determined that a described feature, integer, step, operation, element, and/or component exist/exists, but this does not exclude that one or more other features, integers, steps, operations, elements, components, and/or groups exist or are added. When used herein, the term “and/or” includes any one and all combinations of related listed items.

Embodiments of the present application are described herein with reference to a cross-sectional view as a schematic diagram of an ideal embodiment (and an intermediate structure) of the present application. In this way, a change in a shown shape caused by a fabrication technology, a tolerance, and/or the like may be expected. Therefore, the embodiments of the present application should not be limited to specific shapes of areas shown herein, but include shape deviations caused by fabrication or the like. The areas shown in the figure are used as an example in essence, and shapes thereof are not intended to display actual shapes of areas of a device and are not intended to limit the scope of the present application.

In a BEOL process, a spacing between graphics is excessively wide in a layout manner of a graphic structure prepared by using a conventional technology. Due to an excessively wide spacing, voids are prone to appear in a passivation layer after the passivation layer is deposited and an entire wafer is packaged. Relatively large voids will cause a nearby interconnection structure to fall off. A metal layer located on an upper surface of a silicon oxide film layer is easily pushed up when the interconnection structure falls off, and the metal layer is warped. In this case, metal layers located on the upper surface and a lower surface of the silicon oxide film layer cannot be electrically connected to each other, and there are a lot of gaps near the warped metal layer. Consequently, even if the wafer is packaged, it still cannot work normally in a severe high temperature and high humidity environment.

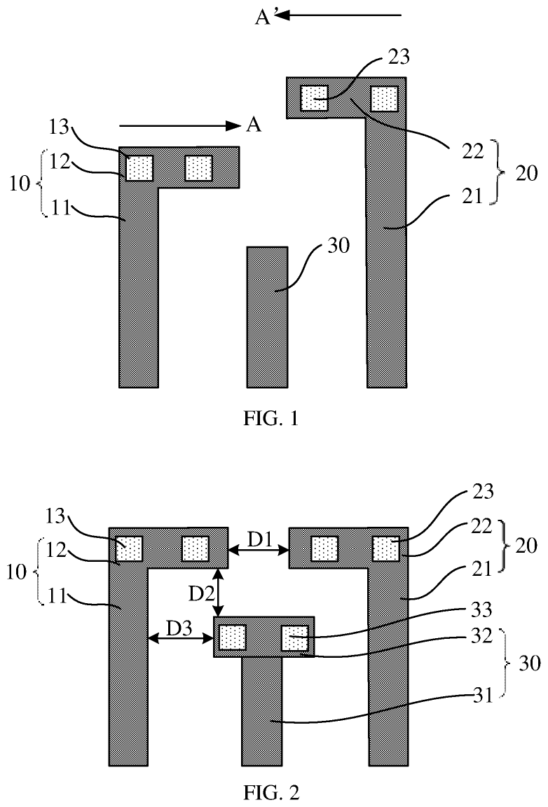

Referring to FIG. 1 to FIG. 4, it should be noted that figures provided in the embodiments only schematically illustrate a basic idea of the present application. Although the figures only show components related to the present application rather than being drawn according to a quantity, shapes, and sizes of the components during actual implementation, forms, the quantity, and a proportion of the components can be changed randomly during actual implementation, and a layout of the components may be more complex.

In an embodiment of the present application, as shown in FIG. 1, a graphic element structure is proposed. The graphic element structure includes a first graphic 10, a second graphic 20, and a third graphic 30. The first graphic 10 includes a first part 11 and a second part 12 that are perpendicular to each other, a tail end of the first part 11 of the first graphic is connected to a head end of the second part 12 of the first graphic, and the second part 12 of the first graphic extends along a first direction A; and orthographic projection of a first interconnection structure 13 on the first graphic 10 is located in the second part 12 of the first graphic. The second graphic 20 includes a first part 21 and a second part 22 that are perpendicular to each other, a tail end of the first part 21 of the second graphic is connected to a head end of the second part 22 of the second graphic, the first part 21 of the second graphic is arranged in parallel to the first part of the first graphic, the second part 22 of the second graphic extends along a second direction A′, and the second direction A′ is opposite to the first direction A; and orthographic projection of a second interconnection structure 23 on the second graphic 20 is located in the second part 22 of the second graphic. The third graphic 30 is located between the first graphic 10 and the second graphic 20.

In the graphic element structure provided in the foregoing embodiment, the first graphic includes the first part and the second part that are perpendicular to each other, the tail end of the first part of the first graphic is connected to the head end of the second part of the first graphic, the second part of the first graphic extends along the first direction, and the orthographic projection of the first interconnection structure of the first graphic on the first graphic is located in the second part of the first graphic; the second graphic includes the first part and the second part that are perpendicular to each other, the tail end of the first part of the second graphic is connected to the head end of the second part of the second graphic, the second part of the second graphic extends along the second direction, the first direction is opposite to the second direction, and the orthographic projection of the second interconnection structure of the second graphic on the second graphic is located in the second part of the second graphic; and the third graphic is located between the first graphic and the second graphic. Compared with a conventional graphic layout structure, a spacing between graphics is smaller in a layout manner of the graphic element structure in the present application. In this way, during a subsequent reliability test after wafer preparation, a smaller spacing can prevent an interconnection structure from falling off and voids in an upper metal film layer caused by falling off of the interconnection structure, thereby improving the reliability of a wafer and prolonging a service life of the wafer.

For example, the first graphic 10 and the second graphic 20 are both in an inverted L shape, such that the first graphic and the second graphic are close to each other, reducing a spacing between the first graphic 10 and the second graphic. A width of the second part 12 of the first graphic may be the same as a width of the first part 11 of the first graphic, and a width of the second part 22 of the second graphic may be the same as a width of the first part 21 of the second graphic. The second part 12 of the first graphic is rotated 90 degrees relative to a graphic structure of the first part 11 of the first graphic to connect the tail end of the first part 11 of the first graphic to the head end of the second part 12 of the first graphic. This improves a spacing area between graphics to avoid a problem that the interconnection structures fall off.

In an embodiment, the first graphic 10, the second graphic 20, and the third graphic 30 are located on a same metal layer. The graphic element structure further includes multiple layers of first graphics 10 arranged in parallel at intervals, multiple layers of second graphics 20 arranged in parallel at intervals, and multiple layers of third graphics 30 arranged in parallel at intervals, and the first graphics 10, the second graphics 20, and the third graphics 30 are perpendicularly stacked. The first interconnection structure 13 is located between adjacent first graphics 10, and the second interconnection structure 23 is located between adjacent second graphics 20. Specifically, first interconnection structures 13 are formed below and above the second part 12 of the first graphic, and second interconnection structures 23 are formed below and above the second part 22 of the second graphic.

In an embodiment, a dielectric layer (not shown) is arranged between adjacent first graphics 10, between adjacent second graphics 20, and between adjacent third graphics 30, and both the first interconnection structure 13 and the second interconnection structure 23 are located in the dielectric layer.

For example, the dielectric layer may include a first metal layer, a silicon oxide layer, and a second metal layer that are sequentially stacked from bottom to top, and the first interconnection structure and the second interconnection structure penetrate through the silicon oxide layer along a thickness direction. A top part of the first interconnection structure and a top part of the second interconnection structure are in contact with the second metal layer, a bottom part of the first interconnection structure and a bottom part of the second interconnection structure are in contact with the first metal layer, and the second metal layer is electrically connected to the first metal layer through the first interconnection structure and the second interconnection structure. A material of the first metal layer may include, but is not limited to, one of tungsten, copper, or aluminum, or an alloy material of any combination thereof. A material of the second metal layer may include, but is not limited to, one of tungsten, copper, or aluminum, or an alloy material of any combination thereof. A material of the first interconnection structure may include, but is not limited to, one of tungsten, copper, or aluminum, or an alloy material of any combination thereof. A material of the second interconnection structure may include, but is not limited to, one of tungsten, copper, or aluminum, or an alloy material of any combination thereof.

In an embodiment, as shown in FIG. 2, a third graphic 30 is in a T shape. The third graphic 30 includes a first part 31 and a second part 32 that are perpendicular to each other. The first part 31 of the third graphic is perpendicularly connected to the second part 32 of the third graphic. The first part 31 of the third graphic is arranged in parallel to both a first part 11 of a first graphic and a first part 21 of a second graphic, and the second part 32 of the third graphic is arranged in parallel to both a second part 12 of the first graphic and a second part 22 of the second graphic.

Specifically, the third graphic 30 further includes a third interconnection structure 33, and orthographic projection of the third interconnection structure 33 on the third graphic 30 is located in the second part 32 of the third graphic, and is symmetrically located on both sides of a center line of the first part 31 of the third graphic.

Further, there are multiple first interconnection structures 13, multiple second interconnection structures 23, and multiple third interconnection structures 33. The multiple first interconnection structures 13 are arranged at intervals along a length direction of the second part 12 of the first graphic, the multiple second interconnection structures 23 are arranged at intervals along a length direction of the second part 22 of the second graphic, and the multiple third interconnection structures 33 are arranged at intervals along a length direction of the second part 32 of the third graphic. The length direction of the second part 12 of the first graphic is a first direction A, the length direction of the second part 22 of the second graphic is a second direction A′, and the length direction of the second part 32 of the third graphic includes the first direction A and the second direction A′. For example, interconnection structures may be arranged at an equal interval along a length direction.

In an embodiment, a length of the second part 32 of the third graphic is greater than a width of the first part 31 of the third graphic, such that a spacing between the second part 32 of the third graphic and the first part 11 of the first graphic is less than a spacing between the first part 31 of the third graphic and the first part 11 of the first graphic.

In an embodiment, a center line of the first part 31 of the third graphic coincides with a center line of the second part 32 of the third graphic; the first graphic 10 and the second graphic 20 are symmetrically distributed along a center line of the third graphic 30; and projection of the second part 12 of the first graphic and projection of the second part 22 of the second graphic in a length direction of the second part 32 of the third graphic separately coincide with the second part 32 of the third graphic partially. Specifically, a projection point of a tail end of the second part 12 of the first graphic in the first direction A is located in the second part 32 of the third graphic, and a projection point of a tail end of the second part 22 of the second graphic in the second direction A′ is located in the second part 32 of the third graphic.

In an embodiment, still referring to FIG. 2, there is a first spacing D1 between the tail end of the second part 12 of the first graphic and the tail end of the second part 22 of the second graphic; there is a second spacing D2 between the second part 12 of the first graphic and the second part 32 of the third graphic, and between the second part 22 of the second graphic and the second part 32 of the third graphic; and a ratio of the first spacing D1 to the second spacing D2 is 0.9-1.1. Specifically, D1/D2 is 0.9, 0.95, 1.0, 1.1, or the like. There is a third spacing D3 between the first part 11 of the first graphic and the second part 32 of the third graphic, and between the first part 21 of the second graphic and the second part 32 of the third graphic; and a ratio of the first spacing D1 to the third spacing D3 is 0.9-1.1. Specifically, D1/D3 is 0.9, 0.95, 1.0, 1.1, or the like.

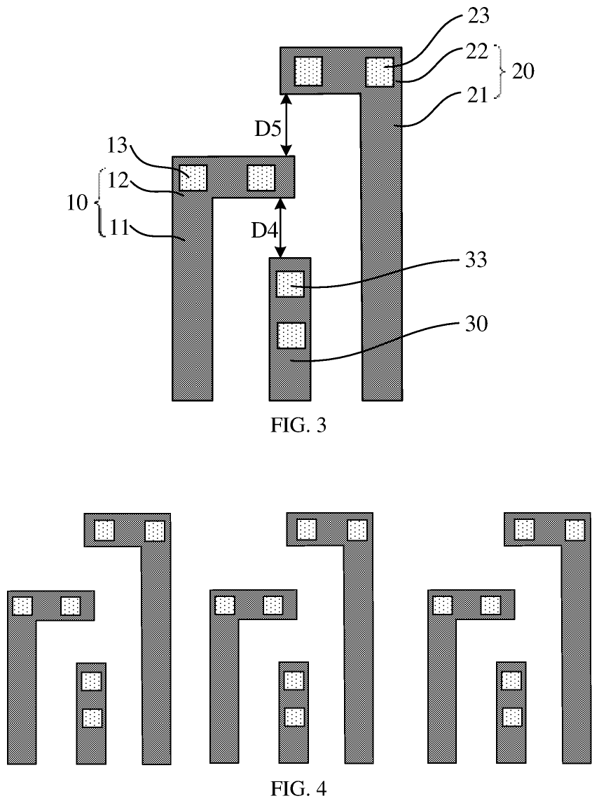

In an embodiment, as shown in FIG. 3, a third graphic 30 is a linear type graphic, and the third graphic 30 is arranged in parallel to both a first part 11 of a first graphic and a first part 21 of a second graphic.

For example, a width of a second part 12 of the first graphic is the same as both a width of the first part 11 of the first graphic and a width of the third graphic 30, and a width of a second part 22 of the second graphic is the same as both a width of the first part 21 of the second graphic and the width of the third graphic 30.

In an embodiment, the third graphic 30 further includes a third interconnection structure 33, and orthographic projection of the third interconnection structure 33 on the third graphic 30 is located in the third graphic 30. There are multiple first interconnection structures 13, multiple second interconnection structures 23, and multiple third interconnection structures 33, the multiple first interconnection structures 13 are arranged at intervals along a length direction of the second part 12 of the first graphic, the multiple second interconnection structures 23 are arranged at intervals along a length direction of the second part 22 of the second graphic, and the multiple third interconnection structures 33 are arranged at intervals along a length direction of the third graphic 30. For example, interconnection structures may be arranged at an equal interval along a length direction.

In an embodiment, projection of the second part 22 of the second graphic and projection of the second part 12 of the first graphic in the length direction of the second part 12 of the first graphic partially coincide with each other; and projection of the third graphic 30, projection of the second part 12 of the first graphic, and projection of the second part 22 of the second graphic in the length direction of the second part 22 of the second graphic partially coincide with each other.

For example, a projection point of a tail end of the second part 12 of the first graphic in a first direction A is located in the third graphic 30, and a projection point of a tail end of the second part 22 of the second graphic in a second direction A′ is located in the second part 12 of the first graphic.

In an embodiment, the second part 12 of the first graphic is located between the second part 22 of the second graphic and the third graphic 30. Specifically, there is a fourth spacing D4 between the second part 12 of the first graphic and the third graphic 30, there is a fifth spacing D5 between the second part 22 of the second graphic and the second part 12 of the first graphic, and a ratio of the fourth spacing D4 to the fifth spacing D5 is 0.9-1.1. Specifically, D4/D5 is 0.9, 0.95, 1.0, 1.1, or the like. There is a sixth spacing (not shown in the figure) between the third graphic 30 and the first part 11 of the first graphic, and between the third graphic 30 and the first part 21 of the second graphic 20; and a ratio of the sixth spacing to the fourth spacing D4 and a ratio of the sixth spacing to the fifth spacing D5 are both 0.9-1.1. The spacings that are close to each other are set between the graphics, such that voids can be avoided in a subsequently deposited passivation layer after metal layers and interconnection structures that are sequentially stacked are formed based on the graphics.

For example, blank areas of the first graphic 10, the second graphic 20, and the third graphic 30 form S-shaped space. This can improve a spacing area between the graphics to avoid a problem that the interconnection structures fall off.

In an embodiment of the present application, a graphic array structure is further provided. The graphic array structure includes multiple graphic element structures described above. The multiple graphic element structures are arranged in an array. To be specific, the graphic element structure formed by a first graphic, a second graphic, and a third graphic is used as a unit, and the graphic element structures are sequentially aligned and arranged along a first direction or a second direction, as shown in FIG. 4. This graphic array structure is only shown as an example, and no limitation is set thereto.

It should be noted that the foregoing embodiments are intended for illustrative purposes only rather than limiting the present application.

Each embodiment in this specification is described in a progressive manner Each embodiment focuses on the difference from other embodiments. For the same and similar parts between the embodiments, mutual reference may be made.

The technical features of the above embodiments can be combined in any manner. For concise description of these embodiments, all possible combinations of all technical features of the embodiments may not be described; however, these combinations of technical features should be construed as disclosed in this specification provided that no contradiction occurs.

Several implementations in the present application are merely described in more detail in the foregoing embodiments, but they should not therefore be construed as limiting the scope of the patent application. It should be noted that persons of ordinary skill in the art can further make several variations and improvements without departing from the conception of the present application. These variations and improvements all fall within the protection scope of the present application. Therefore, the protection scope of the patent application shall be subject to the protection scope defined by the claims.

1. A graphic element structure, comprising:
a first graphic, wherein the first graphic comprises a first part and a second part that are perpendicular to each other, a tail end of the first part of the first graphic is connected to a head end of the second part of the first graphic, and the second part of the first graphic extends along a first direction; and orthographic projection of a first interconnection structure on the first graphic is located in the second part of the first graphic;
a second graphic, wherein the second graphic comprises a first part and a second part that are perpendicular to each other, a tail end of the first part of the second graphic is connected to a head end of the second part of the second graphic, the first part of the second graphic is arranged in parallel to the first part of the first graphic, the second part of the second graphic extends along a second direction, and the second direction is opposite to the first direction; and orthographic projection of a second interconnection structure on the second graphic is located in the second part of the second graphic; and
a third graphic, located between the first graphic and the second graphic.

2. The graphic element structure according to claim 1, wherein the third graphic comprises a first part and a second part that are perpendicular to each other, the first part of the third graphic is perpendicularly connected to the second part of the third graphic, the first part of the third graphic is arranged in parallel to both the first part of the first graphic and the first part of the second graphic, and the second part of the third graphic is arranged in parallel to both the second part of the first graphic and the second part of the second graphic.

3. The graphic element structure according to claim 2, wherein orthographic projection of a third interconnection structure on the third graphic is located in the second part of the third graphic, and is symmetrically located on both sides of a center line of the first part of the third graphic.

4. The graphic element structure according to claim 3, wherein there are multiple first interconnection structures, multiple second interconnection structures, and multiple third interconnection structures; the multiple first interconnection structures are arranged at intervals along a length direction of the second part of the first graphic, the multiple second interconnection structures are arranged at intervals along a length direction of the second part of the second graphic, and the multiple third interconnection structures are arranged at intervals along a length direction of the second part of the third graphic.

5. The graphic element structure according to claim 3, wherein a length of the second part of the third graphic is greater than a width of the first part of the third graphic.

6. The graphic element structure according to claim 2, wherein a center line of the first part of the third graphic coincides with a center line of the second part of the third graphic; the first graphic and the second graphic are symmetrically distributed along a center line of the third graphic; and projection of the second part of the first graphic and projection of the second part of the second graphic in a length direction of the second part of the third graphic separately coincide with the second part of the third graphic partially.

7. The graphic element structure according to claim 6, wherein there is a first spacing between a tail end of the second part of the first graphic and a tail end of the second part of the second graphic is; there is a second spacing between the second part of the first graphic and the second part of the third graphic, and a ratio of the first spacing to the second spacing is 0.9-1.1; and
there is a third spacing between the first part of the first graphic and the second part of the third graphic, and between the first part of the second graphic and the second part of the third graphic; and a ratio of the first spacing to the third spacing is 0.9-1.1.

8. The graphic element structure according to claim 1, wherein the third graphic is linear, and the third graphic is arranged in parallel to the first part of the first graphic and the first part of the second graphic.

9. The graphic element structure according to claim 8, wherein orthographic projection of a third interconnection structure on the third graphic is located in the third graphic.

10. The graphic element structure according to claim 9, wherein there are multiple first interconnection structures, multiple second interconnection structures, and multiple third interconnection structures; the multiple first interconnection structures are arranged at intervals along a length direction of the second part of the first graphic, the multiple second interconnection structures are arranged at intervals along a length direction of the second part of the second graphic, and the multiple third interconnection structures are arranged at intervals along a length direction of the third graphic.

11. The graphic element structure according to claim 8, wherein projection of the second part of the second graphic and projection of the second part of the first graphic, in a length direction of the second part of the first graphic, partially coincide with each other; and projection of the third graphic, projection of the second part of the first graphic, and projection of the second part of the second graphic, in a length direction of the second part of the second graphic, partially coincide with each other.

12. The graphic element structure according to claim 11, wherein the second part of the first graphic is located between the second part of the second graphic and the third graphic.

13. The graphic element structure according to claim 12, wherein there is a fourth spacing between the second part of the first graphic and the third graphic, there is a fifth spacing between the second part of the second graphic and the second part of the first graphic, and a ratio of the fourth spacing to the fifth spacing is 0.9-1.1.

14. The graphic element structure according to claim 1, wherein the first graphic, the second graphic, and the third graphic are located on a same metal layer.

15. The graphic element structure according to claim 1, wherein the graphic element structure comprises multiple layers of first graphics arranged in parallel at intervals, multiple layers of second graphics arranged in parallel at intervals, and multiple layers of third graphics arranged in parallel at intervals; and the first interconnection structure is located between adjacent first graphics, and the second interconnection structure is located between adjacent second graphics.

16. The graphic element structure according to claim 15, wherein a dielectric layer is arranged between adjacent first graphics, between adjacent second graphics, and between adjacent third graphics; and the first interconnection structure and the second interconnection structure are located in the dielectric layer.

17. A graphic array structure, comprising multiple graphic element structures according to claim 1, wherein the multiple graphic element structures are arranged in an array.
